(19) United States
(12) Patent Application Publication
(10) Pub. No.: US 2017/0367182 A1
(43) Pub. Date: Dec. 21, 2017

(54) LASER DIRECT STRUCTURED MATERIALS AND THEIR METHODS OF MAKING

(71) Applicant: SABIC Global Technologies B.V., Bergen op Zoom (NL)

(72) Inventors: Tong WU, Shanghai (CN); Wei FENG, Shanghai (CN); Yangang YAN, Shanghai (CN); Wenjia Zhang, Shanghai (CN); Yuxian AN, Shanghai (CN); Xueming Lian, Shanghai (CN); Mahari TJAHJADI, Shanghai (CN)

(21) Appl. No.: 15/535,087

(22) PCT Filed: Dec. 8, 2015
(86) PCT No.: PCT/IB2015/059448

§ 371 Date: Jun. 12, 2017

Related U.S. Application Data
(60) Provisional application No. 62/091,099, filed on Dec. 12, 2014.

(51) Int. Cl. H05K 1/03; C08K 9/02; C08K 5/00; C08K 3/22; B32B 27/36; H05K 3/18; B32B 27/20

(52) U.S. Cl. CPC H05K 1/0373; H05K 3/185; C08K 9/02; B32B 27/20; C08K 3/2279; B32B 27/36; C08K 5/0041

(57) ABSTRACT

The present disclosure relates to LDS materials comprising a first coating layer comprising a first LDS additive, and a base substrate, wherein the coating layer contacts the base substrate. Articles formed from the LDS materials are also disclosed that include a conductive path and a metal layer deposited on the activated path. Methods for making the LDS materials and corresponding articles are also described.

### RELATED APPLICATIONS

This application claims benefit of U.S. Patent Application No. 62/091,099, filed Dec. 12, 2014, the disclosure of which is incorporated herein in its entirety.

### TECHNICAL FIELD

This disclosure relates to coating materials that comprise a laser direct structuring (LDS) additive. These coating materials can be deposited on a base substrate and expand the application area for LDS additives beyond that available with conventional compounding technology. The present disclosure finds use, for example, in the automotive, electronics, RFID, communications, and medical device industries.

### BACKGROUND OF THE INVENTION

Laser direct structuring (LDS) materials have been extensively used to make molded injection devices (MIDs) via single shot injection molding. In a typical LDS process, a computer-controlled laser beam travels over MIDs to activate a substrate's surface at locations where the conductive path is to be situated. The LDS additives release metallic nuclei which can be reduced to metal to form conductive paths in the subsequent chemical plating process. An advantage of laser direct structuring is its flexibility. If the design of the circuit is changed, it is simply a matter of reprogramming the computer that controls the laser. The LDS process enables conductive path widths and the spacing between the conductive paths of 150 μm or less. Consequently, LDS treated MIDs save space and weight in the end-use applications. Compared to the existing methods such as metal-sheet stamping and 2-shot-molding, LDS facilitates, among other things, short development cycles, variation in design, cost reduction, miniaturization, diversification, and functionality.

A key challenge for this technology, however, is to develop LDS materials with robust plating performance while maintaining good mechanical properties. Also, laser structuring only happens on the surface of the injected part such that most bulk material beneath the surface does not require the presence of LDS additives. LDS additives are expensive and can adversely affect other performance of the bulk materials, such as base resin degradation and filler disintegration during extrusion and molding, long-term stability problems, and lack of ductility.

Also, with emerging market trends, the appearance of a device is becoming increasingly important, especially in consumer electronics. It is well known that LDS materials are rendered dark or opaque owing to the presence of LDS additives and its carriers, which are characterized by a bigger particle size. Although light colored LDS materials with colorable characteristics and good mechanical properties have been reported, the technology used to prepare transparent LDS materials has not progressed. This is attributed to the fact that most LDS additives will affect light transmittance of the overall LDS material due to bigger particle sizes and the higher loading required for sufficient plating performance. Moreover, typically there is weak near-infra red (NIR) absorption for transparent materials which affects plating performance as well as peel strength between the plating layer and base substrate, such as a base resin.

In one aspect, the present disclosure addresses the problems associated with preparing transparent LDS materials. By using the coating materials disclosed herein, a much lower dosage of LDS additives is required, with the base substrate being free of LDS additives. In this way, both the coating layer and base substrate can maintain transparency such that the overall LDS material (coating layer and base substrate) is transparent.

In other aspects, the coating materials may be applied on various base substrates, transparent and non-transparent, including rubber, ceramic, insulated materials, metals, and reinforced materials.

The LDS coating materials described herein expand the LDS application areas and provide much more flexibility than conventional compounding technology (i.e. compounding the LDS additive into the substrate, typically plastic). And due to the lower dosage of LDS additive required, the coating materials provide an efficient and cost effective solution.

### SUMMARY OF THE INVENTION

The present disclosure relates to LDS materials comprising a first coating layer comprising a first LDS additive, and a base substrate, wherein the first coating layer contacts the base substrate.

The present disclosure also relates to a method of forming an LDS material comprising depositing a coating liquid comprising a first LDS additive on a base substrate, and curing the coating liquid on the base substrate to form a first coating layer. An activated path may subsequently be formed on the first coating layer, and a metal layer deposited on the activated path.

Another aspect of the present disclosure relates to articles formed from the disclosed LDS materials, where the article has an activated path and a metal layer deposited on the activated path.

### BRIEF DESCRIPTION OF THE DRAWINGS

The following is a brief description of the drawings, which are exemplary of the various embodiments described herein.

FIG. 1 is a schematic diagram of a process for preparing LDS materials according to one embodiment of the present disclosure.

### DETAILED DESCRIPTION OF ILLUSTRATIVE EMBODIMENTS

Unless defined otherwise, all technical and scientific terms used herein have the same meaning as commonly understood by one of ordinary skill in the art to which this disclosure belongs. Although any methods and materials similar or equivalent to those described herein can be used in the practice or testing of the present disclosure, example methods and materials are now described.

Ranges can be expressed herein as from one particular value, and/or to another particular value. When such a range is expressed, another aspect includes from the one particular value and/or to the other particular value. Similarly, when values are expressed as approximations, by use of the antecedent ‘about,’ it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “about” and “at or about” mean that the amount or value in question can be the value designated some other value approximately or about the same. It is generally understood, as used herein, that it is the nominal value indicated ±10% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

As used herein the terms “weight percent,” “wt. %,” and “wt. %” of a component, which can be used interchangeably, unless specifically stated to the contrary, are based on the total weight of the formulation or composition in which the component is included. For example if a particular element or component in a composition or article is said to have 8% by weight, it is understood that this percentage is relative to a total compositional percentage of 100% by weight.

Disclosed are the components to be used to prepare the compositions of the present disclosure as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the disclosure. Thus, if there are a variety of additional steps that can be performed it is understood that each of these additional steps can be performed with any specific aspect or combination of aspects of the methods of the present disclosure.

All cited patents, patent applications, and other references are incorporated herein by reference in their entirety.

While typical embodiments have been set forth for the purpose of illustration, the foregoing descriptions should not be deemed to be a limitation on the scope herein. Accordingly, various modifications, adaptations, and alternatives can occur to one skilled in the art without departing from the spirit and scope herein.

The present disclosure describes LDS materials comprising a first coating layer comprising a LDS additive, and a base substrate, wherein the first coating layer is in contact with the base substrate.

### Base Substrate

Given the flexibility of the coating materials of the present disclosure, the base substrate may be a formed/shaped substrate of various compositions. For example, the base substrate may be polymeric, metal, ceramic, an inorganic solid (e.g. glass), an organic solid (carbon or graphite or paper or low molecular weight oligomers such as wax), a composite, rubber, wood, insulated material, or reinforced material, or combinations thereof. Typically, the base substrate will not contain any LDS additives, especially in embodiments forming transparent LDS materials.

In certain embodiments, the base substrate is polymeric. In certain aspects, the base substrate comprises a thermoplastic resin or a thermoset resin. The thermoplastic resins include polycarbonate, acrylonitrile-butadiene-styrene, polyimide, a poly(arylene ether), polyamide, polyester, polyphthalamide, polyphenylene oxide, polyetherimide, polyketones, polyetherketones, polybenzimidazole, polystyrene, polymethyl methacrylate, polyvinylchloride, cellulose-acetate resin, polyacrylonitrile, polysulphone, polyphenylenesulfide, fluoropolymers, polycarbonate/acrylonitrile-butadiene-styrene resin blend, acrylonitrile-ethylene/propylene-styrene, methyl methacrylate-butadiene-styrene, acrylonitrile-butadiene-methyl methacrylate-styrene, acrylonitrile-n-butyl acrylate-styrene, rubber modified polystyrene, polyethylene, polypropylene, silicone, polyamide elastomer, and combinations thereof. The thermoplastic resins may also include thermoplastic elastomers such as polyamide and polyester based elastomers. The base substrate can also comprise blends and/or other types of combination of resins described above.

In certain aspects, the polymeric materials are amorphous polymers or crystalline polymers that have been formed with crystallinity low enough to be amenable to producing transparent LDS materials.

Thermosetting polymers can also be used as base substrate and include, for example, phenol resin, urea resin, melamine-formaldehyde resin, urea-formaldehyde latex, xylene resin, diallyl phthalate resin, epoxy resin, aniline resin, furan resin, polyurethane, or combinations thereof.

A preferred base substrate is comprises a polycarbonate polymer. The term polycarbonate as used herein is not intended to refer to only a specific polycarbonate or group of polycarbonates, but rather refers to the any one of the class of compounds containing a repeating chain of carbonate groups. In one aspect, a polycarbonate material can include any one or more of those polycarbonate materials disclosed and described in U.S. Pat. No. 7,786,246, which is hereby incorporated by reference in its entirety for the specific purpose of disclosing various polycarbonate compositions and methods for manufacture of same.

In one aspect, a polycarbonate polymer as disclosed herein can be an aliphatic-diol based polycarbonate. In another aspect, the polycarbonate polymer can comprise a carbonate unit derived from a dihydroxy compound, such as, for example, a bisphenol that differs from the aliphatic diol. In still further aspects, an exemplary polycarbonate polymer includes aromatic polycarbonates conventionally manufactured through a transesterification reaction of an one or more aromatic dihydroxy compound(s) and a carbonic acid diester in the presence of one or more catalyst(s).

In one aspect, non-limiting examples of suitable bisphenol compounds include the following: 4,4′-dihydroxybiphenyl, 1,6-dihydroxynaphthalene, 2,6-dihydroxynaphthalene, bis(4-hydroxyphenyl)methane, bis(4-hydroxyphenyl)diphenylmethane, bis(4-hydroxyphenyl)-1-naphthylmethane, 1,2-bis(4-hydroxyphenyl)ethane, 1,1-bis(4-hydroxyphenyl)-1-phenylethane, 2-(4-hydroxyphenyl)-2-(3-hydroxyphenyl)propane, bis(4-hydroxyphenyl)phenylmethane, 2,2-bis(4-hydroxy-3-bromophenyl)propane, 1,1-bis(hydroxyphenyl)cyclopentane, 1,1-bis(4-hydroxyphenyl)cyclohexane, 1,1-bis(4-hydroxy-3 methylphenyl)cyclohexane 1,1-bis(4-hydroxyphenyl)isobutene, 1,1-bis(4-hydroxyphenyl)cyclododecane, trans-2,3-bis(4-hydroxyphenyl)-2-butene, 2,2-bis(4-hydroxyphenyl)adamantine, (alpha, alpha′-bis(4-hydroxyphenyl)toluene, bis(4-hydroxyphenyl)acetonitrile, 2,2-bis(3-methyl-4-hydroxyphenyl)propane, 2,2-bis(3-ethyl-4-hydroxyphenyl)propane, 2,2-bis(3-n-propyl-4-hydroxyphenyl)propane, 2,2-bis(3-isopropyl-4-hydroxyphenyl)propane, 2,2-bis(3-sec-butyl-4-hydroxyphenyl)propane, 2,2-bis(3-t-butyl-4-hydroxyphenyl)propane, 2,2-bis(3-cyclohexyl-4-hydroxyphenyl)propane, 2,2-bis(3-allyl-4-hydroxyphenyl)propane, 2,2-bis(3-methoxy-4-hydroxyphenyl)propane, 2,2-bis(4-hydroxyphenyl)hexafluoropropane, 1,1-dichloro-2,2-bis(4-hydroxyphenyl)ethylene, 1,1-dibromo-2,2-bis(4-hydroxyphenyl)ethylene, 1,1-dichloro-2,2-bis(5-phenoxy-4-hydroxyphenyl)ethylene, 4,4′-dihydroxybenzophenone, 3,3-bis(4-hydroxyphenyl)-2-butanone, 1,6-bis(4-hydroxyphenyl)-1,6-hexanedione, ethylene glycol bis(4-hydroxyphenyl)ether, bis(4-hydroxyphenyl)ether, bis(4-hydroxyphenyl) sulfide, bis(4-hydroxyphenyl)sulfoxide, bis(4-hydroxyphenyl)sulfone, 9,9-bis(4-hydroxyphenyl)fluorene, 2,7-dihydroxypyrene, 6,6′-dihydroxy-3,3,3′,3′-tetramethylspiro(bis)indane (“spirobiindane bisphenol”), 3,3-bis(4-hydroxyphenyl)phthalide, 2,6-dihydroxydibenzo-p-dioxin, 2,6-dihydroxythianthrene, 2,7-dihydroxyphenoxathin, 2,7-dihydroxy-9,10-dimethylphenazine, 3,6-dihydroxydibenzofuran, 3,6-dihydroxydibenzothiophene, and 2,7-dihydroxycarbazole, and the like, as well as combinations comprising at least one of the foregoing dihydroxy aromatic compounds.

In another aspect, exemplary bisphenol compounds can comprise 1,1-bis(4-hydroxyphenyl)methane, 1,1-bis(4-hydroxyphenyl)ethane, 2,2-bis(4-hydroxyphenyl)propane (hereinafter “bisphenol A” or “BPA”), 2,2-bis(4-hydroxyphenyl)butane, 2,2-bis(4-hydroxyphenyl)octane, 1,1-bis(4-hydroxyphenyl)propane, 1,1-bis(4-hydroxyphenyl)n-butane, 2,2-bis(4-hydroxy-1-methylphenyl)propane, 1,1-bis(4-hydroxy-t-butylphenyl)propane, 3,3-bis(4-hydroxyphenyl)phthalimidine, 2-phenyl-3,3-bis(4-hydroxyphenyl)phthalimidine (“PPPBP”), and 9,9-bis(4-hydroxyphenyl)fluorene. Combinations comprising at least one dihydroxy aromatic compound can also be used. In another aspect, other types of diols can be present in the polycarbonate.

In a yet another aspect, polycarbonates with branching groups can be useful, provided that such branching does not significantly adversely affect desired properties of the polycarbonate. Branched polycarbonate blocks can be prepared by adding a branching agent during polymerization. These branching agents include polyfunctional organic compounds containing at least three functional groups selected from hydroxyl, carboxyl, carboxylic anhydride, haloformyl, and mixtures of the foregoing functional groups. Specific examples include trimellitic acid, trimellitic anhydride, trimellitic trichloride, tris-p-hydroxy phenyl ethane, isatin-bis-phenol, tris-phenol TC (1,3,5-tris((p-hydroxyphenyl)isopropyl)benzene), tris-phenol PA (4(4(1,1-bis(p-hydroxyphenyl)-ethyl) alpha, alpha-dimethylbenzyl)phenol), 4-chloroformyl phthalic anhydride, trimesic acid, and benzophenone tetracarboxylic acid. In one aspect, a branching agent can be added at a level of about 0.05 to about 2.0 wt %. In a still another aspect, mixtures comprising linear polycarbonates and branched polycarbonates can be used.

The polycarbonate polymer can comprise copolymers comprising carbonate units and other types of polymer units, including ester units, and combinations comprising at least one of homopolycarbonates and copolycarbonates. An exemplary polycarbonate copolymer of this type is a polyester carbonate, also known as a polyester-polycarbonate. Such copolymers further contain carbonate units derived from oligomeric ester-containing dihydroxy compounds (also referred to herein as hydroxy end-capped oligomeric acrylate esters). In another aspect, the polycarbonate does not comprise a separate polymer such as a polyester. In one aspect, an aliphatic-based polycarbonate comprises aliphatic units that are either aliphatic carbonate units derived from aliphatic diols, or a combination of aliphatic ester units derived from aliphatic diacids having greater than 13 carbons.

In one aspect, the LDS materials of the present disclosure comprises a base substrate that is planar, cylindrical, spherical, annular, tubular, ovoid, a regular 3-D shape, or an irregular 3-D shape. Depending on the shape and configuration of the base substrate, the coating layer may be applied on one or more surfaces of the substrate, including a top surface or bottom surface of a planar substrate, or an inside surface of substrates having cavities, such as those having an annular or tubular shape. For example, the base substrate may be a polymeric sheet having a top surface and a bottom surface.

### Coating Layer

The coating layer is typically prepared from a coating liquid that comprises the LDS additive, a monomer, optionally an oligomer, a photoinitiator, and/or a diluting agent.

In one embodiment, the coating liquid comprises acrylate monomers and/or acrylate oligomer components. In certain aspects, such components include isobornyl acrylate, 1,6-hexanediol diacrylate, polyethylene glycol (400) diacrylate, propoxylated 2 neopentyl glycol diacrylate, tripropylene glycol diacrylate, trimethylolpropane triacrylate, pentaerythritol triacrylate, dipentaerythritol tetraacrylate, aliphatic urethane acrylate, or combinations thereof.

For example, in certain aspects, monomers can include monomers having a plurality of acrylate or methacrylate moieties. These can be di-, tri-, tetra- or penta-functional, specifically di-functional, in order to increase the crosslink density of the cured coating and therefore to increase modulus without causing brittleness. Examples of polyfunctional monomers include, but are not limited, to C₆-C₁₂ hydrocarbon diol diacrylates or dimethacrylates such as 1,6-hexanediol diacrylate and 1,6-hexanediol dimethacrylate; tripropylene glycol diacrylate or dimethacrylate; neopentyl glycol diacrylate or dimethacrylate; propoxylated 2 neopentyl glycol propoxylate diacrylate or dimethacrylate; neopentyl glycol ethoxylate diacrylate or dimethacrylate; 2-phenoxylethyl (meth)acrylate; alkoxylated aliphatic (meth)acrylate; polyethylene glycol (meth)acrylate; lauryl (meth)acrylate, isodecyl (meth)acrylate, isobornyl (meth)acrylate, tridecyl (meth)acrylate; and mixtures comprising at least one of the foregoing monomers. For example, the monomer can be 1,6-hexanediol diacrylate (HDDA), alone or in combination with another monomer, such as tripropyleneglycol diacrylate (TPGDA), trimethylolpropane triacrylate (TMPTA), oligotriacrylate (OTA 480), or octyl/decyl acrylate (ODA).

Oligomers can include, but are not limited to, multifunctional aliphatic urethane acrylates that are part of the following families: the PHOTOMER™ Series of aliphatic urethane acrylate oligomers from IGM Resins, Inc., St. Charles, Ill.; the Sartomer SR Series of aliphatic urethane acrylate oligomer from Sartomer, Exton, Pa.; the Echo Resins Series of aliphatic urethane acrylate oligomers from Echo Resins and Laboratory, Versailles, Mo.; the BR Series of aliphatic urethane acrylates from Bomar Specialties, Winsted, Conn.; and the EBECRYL™ Series of aliphatic urethane acrylate oligomers from Allnex, Smyrna, Ga. For example, the aliphatic urethane acrylates can be KRM8452 (10 functionality, Allnex), EBECRYL1290™ (6 functionality, Allnex), EBECRYL 129ON™ (6 functionality, Allnex), EBECRYL512™ (6 functionality, Allnex), EBECRYL 8702™ (6 functionality, Allnex), EBECRYL8405™ (3 functionality, Allnex), EBECRYL 8402™ (2 functionality, Allnex), EBECRYL284™ (3 functionality, Allnex), EBECRYL 8215™ (2 functionality, Allnex), CN9010* (Sartomer), CN9013™ (Sartomer).

In those aspects involving UV-curing of the coating, the coating liquid may include photoinitiators, such as an alpha hydroxy ketone photoinitiator (e.g. Irgacure® 184 from BASF). Photoinitiators can include, but are not limited to, the following: hydroxycyclohexylphenyl ketone; hydroxymethylphenylpropanone; dimethoxyphenylacetophenone; 2-methyl-1-[4-(methylthio)phenyl]-2-morpholinopropanone-1; 1-(4-isopropylphenyl)-2-hydroxy-2-methylpropan-1-one; 1-(4-dodecylphenyl)-2-hydroxy-2-methylpropan-1-one; 4-(2-hydroxyethoxy) phenyl-(2-hydroxy-2-propyl) ketone; diethoxyacetophenone; 2,2-di-sec-butoxyacetophenone; diethoxy-phenyl acetophenone; bis (2,6-dimethoxybenzoyl)-2,4-, 4-trimethylpentylphosphine oxide; 2,4,6-trimethylbenzoyldiphenylphosphine oxide; 2,4,6-trimethylbenzoylethoxyphenylphosphine oxide; and combinations comprising at least of the foregoing.

Exemplary photoinitiators include phosphine oxide photoinitiators. Examples of such photoinitiators include the IRGACURE™, LUCIRIN™ and DAROCURE™ series of phosphine oxide photoinitiators available from BASF Corp.; the ADDITOL™ series from Cytec Industries; and the ESACURE™ series of photoinitiators from Lamberti, s.p.a. Other useful photoinitiators include ketone-based photoinitiators, such as hydroxy- and alkoxyalkyl phenyl ketones, and thioalkylphenyl morpholinoalkyl ketones. Also suitable are benzoin ether photoinitiators. Specific exemplary photoinitiators are bis(2,4,6-trimethylbenzoyl)-phenylphosphine oxide supplied as IRGACURE™ 819 by BASF or 2-hydroxy-2-methyl-1-phenyl-1-propanone supplied as ADDITOL HDMAP™ by Cytec Industries or 1-hydroxy-cyclohexyl-phenyl-ketone supplied as IRGACURE™ 184 by BASF or 2-hydroxy-2-methyl-1-phenyl-1-propanone supplied as DAROCURE™ 1173 by BASF.

In those aspects involving thermo-curing of the coating, thermal cure components include, but are not limited to, the following: isocyanate-containing components, epoxy-containing components, amine- or hydroxyl-containing components. For example, the isocyanate-containing component can be Desmodur N3390 BA from Bayer, the hydroxyl-containing component can be CY472 E-57 from DSM.

Examples of diluting agents include solvents such as butyl acetate. Other diluting agents include, without limitation, ethyl acetate, isopropanol, n-butanol, 1-methoxy 2-propanol, ethylene glycol monoethyl ether, or mixtures thereof.

### LDS Additives

The coating layer also comprises the LDS additive. As used herein, a laser direct structuring additive refers to metal containing additives suitable for use in a laser direct structuring process. To that end, as discussed more fully herein, an LDS additive is selected such that, after activating with a laser, a conductive path can be formed by a subsequent standard metallization or plating process. As such, when the LDS additive is exposed to a laser, elemental metal is released or activated. The laser thus draws the circuit pattern onto the thermoplastic part and leaves behind a roughened surface containing embedded metal particles. These particles act as nuclei for the crystal growth during a subsequent metallization or plating process, such as a copper plating process or other plating processes, including gold plating, nickel plating, silver plating, zinc plating, tin plating or the like.

According to aspects of the disclosure, the laser direct structuring additive can comprise one or more metal oxides, including for example, oxides of chromium, copper, or combinations thereof. These laser direct structuring additives can also be provided having spinel type crystal structures. An exemplary and non-limiting example of a commercially available laser direct structuring additive includes PK3095 black pigment, commercially available from Ferro Corp., USA. The PK3095, for example, comprises chromium oxides (Cr₂O₃, Cr₂O₄²⁻, Cr₂O₇²⁻) and oxides of copper (CuO), as determined using XPS. The PK3095 black pigment also has a spinel type crystal structure. Another exemplary commercially available laser direct structuring additive is the Black 1G pigment black 28 commercially available from The Shepherd Color company. The Black 1G pigment black 28 comprises copper chromate and has a pH of about 7.3. The Black 1G pigment also has a spinel type crystal structure.

The LDS additive may comprise laser sensitive materials (e.g., at 1064 nm wavelength) including the metal oxide or salts of Sb, Cu, Pb, Ni, Fe, Sn, Cr, Mn, Ag, Au and Co. The LDS additive may comprise a copper chromium oxide spinel, a copper salt, a copper hydroxide phosphate, a copper phosphate, a copper sulfate, a cuprous thiocyanate, a spinel based metal oxide, a copper chromium oxide, an organic metal complex, a palladium/palladium-containing heavy metal complex, a metal oxide, a metal oxide-coated filler, antimony doped tin oxide coated on mica, a copper containing metal oxide, a zinc containing metal oxide, a tin containing metal oxide, a magnesium containing metal oxide, an aluminum containing metal oxide, a gold containing metal oxide, a silver containing metal oxide, or a combination thereof.

In certain aspects, the LDS additives comprises metal oxide containing copper, for example, copper chromium oxide spinel, copper hydroxide phosphate, and/or copper phosphate.

The LDS additive concentration in the coating layer is in the range of from about 2% to about 30% by weight based on the weight of the coating layer on a dry basis. In other embodiments the LDS additive is in the range of from about 2% to about 5% by weight based on the weight of the coating layer on a dry basis. For example, the LDS additive may be from about 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, or 30% by weight based on the weight of the coating layer on a dry basis or within a range defined by any two of these values.

In other embodiments, the coating layer comprises from about 0.1 to about 10% by weight, based on the weight of the coating layer, of an ingredient selected from the group consisting of a dye, a pigment, a colorant, and a combination thereof.

Depending on the application and/or substrate to be coated, the thickness of the coating layer, after curing, is from about 3 μm to about 50 μm. In certain embodiments the thickness after curing is from about 5 μm to about 25 μm. For example, the coating layer may be a thickness of about 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50 μm after curing or within a range defined by any two of these values. As used herein “μm” means micrometer or micron.

### Transparent LDS Materials

As noted herein, the coating materials of the present disclosure are particularly useful in producing transparent LDS materials and articles. As used herein, an LDS material is considered transparent if it has greater than or equal to 60% light transmittance and less than or equal to 40% haze as measured according to ASTM D1003-00(B) (unless specified to the contrary herein, all test standards herein are the most recent standard in effect at the effective filing date of this application). With respect to transparent LDS materials, the coating layer and base substrate are typically both separately transparent, and the LDS material itself (i.e. the coating layer and base substrate together) is also able to be transparent, typically having greater than 90% light transmittance and less than 25% haze.

For example, the transparent LDS materials described herein have a light transmittance of 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, or 100%, or within a range defined by any two of these values.

Similarly, the transparent LDS material described herein have haze values of from 0, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, or 40%, or within a range defined by any two of these values.

In the transparent LDS embodiments, the LDS additive is typically only in the coating layer and typically in the range of from about 2% to about 5% by weight based on the weight of the coating layer on a dry basis, including from about 2%, 3%, 4%, or 5%, or within a range defined by any two of these values.

### LDS Material Configurations

A key aspect of the present disclosure is the flexibility available from utilizing the coating materials described herein. For example, the coating layer does not have to be present on the entire surface of the base substrate. In this way, the coating layer may be deposited only in the areas and/or patterns that will require plating. This provides an economical and precision advantage. For example, the coating layer may cover from 10, 20, 30, 40, 50, 60, 70, 80, 90, or 100% of the base substrate surface, or within a range defined by any two of these values.

In addition, more than one distinct coating layer may be used on any one base substrate, with a first and second coating layer being different in chemical and/or physical composition, including comprising different LDS additives, different concentrations of LDS additives, different particle sizes of LDS additives, and/or different thicknesses. The first and second coating layers may be deposited side-by-side or one on top of the other. For example, a base substrate that is a polymeric sheet or other planar shape having a top surface and bottom surface may have a first coating layer on the top surface and a second coating layer on the bottom surface. In yet another embodiment, the base substrate may be coated with a coating layer such that the concentration of LDS additive varies in one direction and/or one location as opposed to another, and/or the thickness of the coating layer varies as well.

In other embodiments, the LDS materials may include stacking or otherwise combining more than one LDS material (i.e. more than one coating layer/base substrate structure). As with the coatings, in such embodiments, the base substrates may also be different in chemical and/or physical composition, including differences in type (polymeric/ceramic/wood), thickness, and/or shape. With respect to polymeric base substrates, a first base substrate may have a different molecular weight then another base substrate.

Given the flexibility of configuration, the LDS materials may be configured with different circuitry, color, or plating patterns in different locations and/or surfaces of the overall LDS material, and/or different locations of a combined or stacked LDS material structure having multiple base substrates.

These configurations may be made as described herein. For example, the described coating/curing/plating cycle may be repeated as a first coating layer is deposited on a second coating layer.

### Process of Making the LDS Materials

The LDS materials are generally prepared by depositing a coating liquid comprising a first LDS additive on a base substrate, and curing the coating liquid on the base substrate to form a first coating layer. As needed, any solvent from the coating layer may be evaporated before or during curing. The curing may be a thermal cure or UV cure. An activated path may subsequently be formed on the first coating layer, and a metal layer deposited on the activated path.

The deposition techniques include spray coating, dip coating, bar coating, flow coating, powder coating, solution casting, roll-to-roll coating, screen printing, atomization, or combinations thereof. In particular, spray coating, bar coating, flow coating, powder coating and solution-casting are typically used.

If needed, a diluting solvent may be evaporated from the coating layer at a temperature of about 25-70° C. (as used herein “° C.” means degree Celsius) for about 1 to about 30 minutes. This is an optional step as the solvent may simply vaporize depending upon its volatility. Standard drying techniques can be used for removing the solvent, including vacuum drying.

A UV cure typically involves a fast curing process in which a high intensity UV (ultraviolet) lamp is used to create a photochemical reaction that instantly cures coatings. In a typical dip coating process, for example, a substrate is dipped into a coating liquid tank for several seconds. The substrate is removed from the tank and placed into an oven for drying for about 20 minutes at 40° C. to remove diluting agent completely, and is cured by Fusion UV with UVA (e.g. 400-315 nm per ISO-21348) intensity at >1000 mW/cm² and UV energy at >350 mJ/cm². As used herein, “nm” means nanometer; “mW/cm²” means milliwatt/centimeter squared; and “mJ/cm²” means millijoule/centimeter squared.

A thermal cure typically involves a curing process at high temperature in which an oven is used to generate a thermal-chemical reaction that cures coatings. In a typical thermal curing process, a substrate is dipped into a coating liquid tank for several seconds. Then the substrate is removed from the tank and placed into an oven at 40 to 130° C. for 20 to 150 minutes to remove diluting agent and to complete the thermal cure.

Typically, a laser is used to form an activated/conductive path during a laser structuring step. In one aspect, laser direct structuring comprises laser etching, and in a further aspect, laser etching is carried out to provide an activated surface. In a further aspect, at least one laser beam draws at least one pattern on the surface of the coating layer during the laser structuring step. In a still further aspect, the LDS additive may release at least one metallic nucleus. In yet a further aspect, the at least one metallic nucleus that has been released may act as a catalyst for a reductive copper plating process.

In a further aspect, laser etching is carried out at about 1 w to about 10 w power with a frequency from about 30 kHz to about 110 kHz and a speed of about 1 m/s to about 5 m/s. In a still further aspect, laser etching is carried out at about 1 w to about 10 w power with a frequency from about 40 kHz to about 100 kHz and a speed of about 2 m/s to about 4 m/s. In a yet further aspect, laser etching is carried out at about 3.5 w power with a frequency of about 40 kHz and a speed of about 2 m/s. As used herein “w” means watts; “kHz” or “KHz” means kilohertz; “m/s” means meter/second.

In a further aspect, a rough surface may form in the LDS process. In a still further aspect, the rough surface may entangle the copper plate with the coating layer material which may provide adhesion between the copper plate and the coating layer.

A metalizing step can, in various aspects, be performed using conventional techniques. For example, in one aspect, an electroless copper plating bath is used during the metallization step in the LDS process. Thus, in various aspects, plating a metal layer onto a conductive path is metallization. In a still further aspect, metallization can comprise the steps: a) cleaning the etched surface; b) additive build-up of tracks; and c) plating.

The LDS additive can remain on the surface of the coating layer in the areas not irradiated by the laser. In one embodiment, the metal layer has a peel strength of 0.7 N/mm (as used herein “N/mm” means newton/millimeter) or higher (ASMT D1876-08). In still another embodiment, the metal layer has a peel strength of 0.8 N/mm or higher. The thickness of the metal layer is, in one embodiment, 0.8 microns or higher. In another embodiment, the thickness of the metal layer is 1.0 microns or higher. In other embodiments the thickness of the metal is from about 30 microns to about 35 microns.

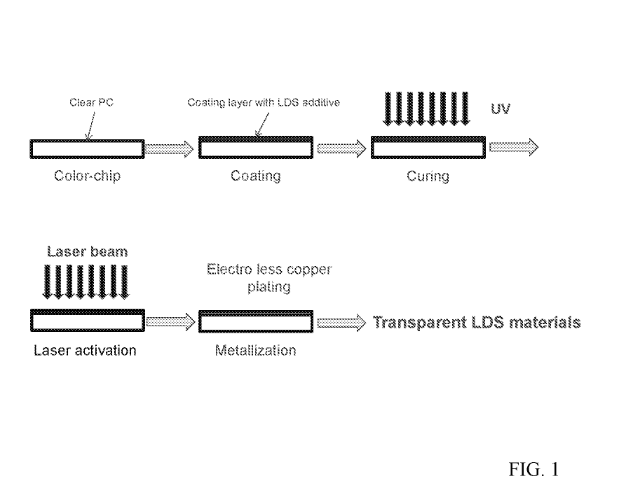

FIG. 1 describes a general process for preparing the LDS materials of the present disclosure. Although directed to an embodiment for forming transparent LDS materials, the process is applicable to other (e.g. non-transparent) embodiments. In this example, a clear polycarbonate (PC) thermoplastic is provided as the base substrate of the to-be-formed transparent LDS material. The base substrate is selected according to the use of the material in the field, for example, in electronic applications, one may use polycarbonate, acrylonitrile-butadiene-styrene, or the polymethyl methacrylate material. The material is selected considering the harshness of the use conditions, such as temperature, chemical environment, weather conditions, level of human interaction, mechanical wear and handle-ability.

As shown in FIG. 1, a coating layer comprising an LDS additive, photoinitiator, and/or diluting solvent is deposited using any one of the coating techniques described herein. In this embodiment, a UV-based coating liquid is used as the base carrier for LDS additives. Alternatively, in other embodiments, a coating liquid comprising thermal curing additives can be used. In other embodiments, the coating liquid can be formulated to have both UV-based as well as thermal curing components.

In the FIG. 1 embodiment, ultraviolet light on the coating layer activates the photoinitiator, which goes on to initiate the curing reaction resulting in a cured coating layer on the base substrate. UV light is electromagnetic radiation with a wavelength in the range 10 nm to 400 nm (as used herein “nm” means nanometer). In the next step, a laser beam is used to draw patterns on the surface of the coating layer. In one embodiment, the laser pattern will be computer program controlled. In the final step, the coating layer is metallized. Metallization is accomplished in an electroless copper plating (chemical plating) bath and copper is deposited on the paths defined by the laser pattern formed in the previous step.

Articles that may be manufactured from the LDS materials of the present disclosure include parts related to a computer, a cell phone, communications equipment, a medical device, an RFID device, or an automotive part. For example, applications for this disclosure include three-dimensional printed circuit boards; mechatronic components for automatic steering wheels, and antennas for mobile phones.

### Aspects

The present disclosure comprises at least the following aspects:

Aspect 1. A laser direct structuring (LDS) material, comprising: a first coating layer comprising a first LDS additive, and a base substrate; wherein the first coating layer contacts the base substrate.

Aspect 2. The LDS material of claim 1, wherein the LDS material has greater than 60% light transmittance and less than 40% haze as measured by ASTM D1003-00(B).

Aspect 3. The LDS material of claim 1, wherein the base substrate comprises polymer, metal, ceramic, glass, non-metallic solids, paper, wax, composites, rubber, paper, wood, insulation materials, reinforced polymeric materials, or combinations thereof.

Aspect 4. The LDS material of any of Aspects 1-3, wherein the base substrate is a thermoplastic or a thermosetting resin.

Aspect 5. The LDS material of Aspect 4, wherein the thermoplastic resin is selected from the group consisting of polycarbonate, acrylonitrile-butadiene-styrene, polyimide, poly(arylene ether), polyamide, polyester, polyphthalamide, polyphenylene oxide, polyetherimide, polyketones, polyetherketones, polybenzimidazole, polystyrene, polymethyl methacrylate, polyvinylchloride, cellulose-acetate, polyacrylonitrile, polysulphone, polyphenylenesulfide, fluoropolymers, polycarbonate/acrylonitrile-butadiene-styrene resin blend, acrylonitrile-ethylene/propylene-styrene, methyl methacrylate-butadiene-styrene, acrylonitrile-butadiene-methyl methacrylate-styrene, acrylonitrile-n-butyl acrylate-styrene, rubber modified polystyrene, polyethylene, polypropylene, silicone, polyamide elastomer, polyester based elastomers, and combinations thereof.

Aspect 6. The LDS material of Aspect 4, wherein the thermosetting resin is selected from the group consisting of phenol resin, urea resin, melamine-formaldehyde resin, urea-formaldehyde latex, xylene resin, diallylphthalate resin, epoxy resin, aniline resin, furan resin, polyurethane, and combinations thereof.

Aspect 7. The LDS material of any of Aspects 1-6, wherein the base substrate is a polycarbonate.

Aspect 8. The LDS material of any of Aspects 1-7, wherein the first LDS additive comprises from about 2% to about 5% by weight of the coating layer.

Aspect 9. The LDS material of any of Aspects 1-8, wherein the first LDS additive is selected from the group consisting of copper chromium oxide spinel, copper hydroxide phosphate, copper phosphate, copper chromium oxide spinel, a copper sulfate, a cuprous thiocyanate, an organic metal complex, a palladium/palladium-containing heavy metal complex, a metal oxide, a metal oxide-coated filler, antimony doped tin oxide coated on mica, a copper containing metal oxide, a zinc containing metal oxide, a tin containing metal oxide, a magnesium containing metal oxide, an aluminum containing metal oxide, a gold containing metal oxide, a silver containing metal oxide, and a combination thereof.

Aspect 10. The LDS material of any of Aspects 1-9, wherein the first LDS additive comprises copper chromium oxide spinel, copper hydroxide phosphate, copper phosphate, or mixtures thereof.

Aspect 11. The LDS material of any of Aspects 1-10, wherein the first coating layer is prepared from a coating liquid that is amenable to UV curing, thermal curing, or a combination thereof.

Aspect 12. The LDS material of Aspect 11, wherein the coating liquid comprises the first LDS additive, a monomer, an oligomer, a photoinitiator, or a diluting agent, or combinations thereof.

Aspect 13. The LDS material of any of Aspects 1-12, wherein the first coating layer has a thickness from about 3 μm to about 50 μm.

Aspect 14. The LDS material of any of Aspects 1-13, wherein the first coating layer has a thickness from about 5 μm to about 25 μm.

Aspect 15. The LDS material of any of Aspects 1-14, wherein the first coating layer comprises from about 0.1 to about 10% by weight, based on the weight of the first coating layer, of an ingredient selected from the group consisting of a dye, a pigment, a colorant, and a combination thereof.

Aspect 16. The LDS material of any of Aspects 1-15, wherein the base substrate is a polymeric sheet having a top surface and a bottom surface, wherein the first coating layer comprising the first LDS additive contacts the top surface of the polymeric sheet and a second coating layer comprising a second LDS additive contacts the bottom surface of the polymeric sheet.

Aspect 17. The LDS material of any of Aspects 1-16, wherein the base substrate is planar, cylindrical, spherical, annular, tubular, ovoid, a regular 3-D shape, or an irregular 3-D shape.

Aspect 18. A method of forming the LDS material of any of Aspects 1-17, comprising: depositing a coating liquid comprising a first LDS additive on a base substrate; and curing the coating liquid on the base substrate to form a first coating layer.

Aspect 19. The method of Aspect 18, wherein the coating liquid is deposited by spray coating, dip coating, bar coating, flow coating, powder coating, solution casting, roll-to-roll coating, screen printing, atomization, or combinations thereof.

Aspect 20. The method of Aspects 18 or 19, further comprising forming an activated path on the first coating layer by laser structuring; and depositing a metal layer on the activated path.

Aspect 21. The method of Aspect 20, wherein the metal layer is deposited on the activated path by electroless plating.

Aspect 22. An article of manufacture formed from the LDS material of any of Aspects 1-17, wherein an activated path is formed on the first coating layer by laser structuring and a metal layer is deposited on the activated path.

Aspect 23. The article of Aspect 22, wherein the article is selected from a computer, a cell phone, communications equipment, a medical device, an RFID device, or an automotive part.

### Example 1

In the samples below, coatings were formulated as 100% solids and then diluted to 80% with butyl acetate as a diluting agent. The coating compositions are shown in Table 1.

A UV-based coating liquid was used as the base carrier for LDS additives. The main components of the UV-based coating include acrylate monomers, acrylate oligomers, photoinitiators, diluting agents and additives. For this example, 1,6-hexanediol diacrylate (HDDA, SR238 from Sartomer), trimethylolpropane triacrylate (TMPTA, SR351 from Sartomer), and aliphatic urethane acrylate (CN9010 from Sartomer) were used. Irgacure® 184 from BASF was used as the photoinitiator to facilitate curing of the coating under UV exposure. Copper hydroxide phosphate, purchased from the Merck Chemical Co., was used as the LDS additive.

The base substrate used for each of the samples was a transparent polycarbonate (Lexan® 141) color chip. The coating layer was deposited on the substrates by a bar coating process in which the coating liquid was applied to the surface of the color chip and a bar was used to drag the coating liquid uniformly. The coated color chip was then put in an oven for about 10 minutes at 40° C. to remove diluting agent, and was cured by Fusion UV, H bulb, with UVA intensity at 1700 mW/cm² and UV energy at 480 mJ/cm².

TABLE 1
Coating Composition (% Wt. of the Composition)

| | | | | | Copper |
|---|---|---|---|---|---|
| | | | CN | Irgacure | Hydroxide |
| No. | SR 238 | SR 351 | 9010 | (R) 184 | Phosphate |
| 1. | 40 | 40 | 13 | 7 | 2 |
| 2. | 40 | 40 | 13 | 7 | 3 |

TABLE 2
Light Transmittance and Haze

| | LDS Additive | | |
|---|---|---|---|
| No. | Loading | Transmittance % | Haze % |
| 1. | 2% | 92.0 +/− 0.1 | 16.6 +/− 0.6 |
| 2. | 3% | 91.9 +/− 0.1 | 22.8 +/− 1.8 |

All samples manifested a greater than 90% light transmittance and less than 25% haze according to ASTM D1003-00(B).

All samples also demonstrated good plating performance in addition to good transparency. Plating index (PI) values for the two samples were greater than 0.7, indicating good plating performance. Plating index was determined by testing the plated copper thickness using the XRF method with ASTM B568 standard. Below are the PI testing results for Samples 1 and 2 based on the listed power, frequency, and speed:

| 1# | | | | | | |
|---|---|---|---|---|---|---|
| 10 w/100 KHZ | 10 W 70 KHZ | 10 w/40 KHZ | 2 w/100 KHZ | 2 w 70 KHZ | 2 w 40 KHZ | |
| spd = 2 m/s | spd = 2/m/s | spd = 2 m/s | spd = 2 m/s | spd = 2 m/s | spd = 2 m/s | |
| 1.59 | 1.66 | 1.55 | 0.00 | 0.16 | 0.44 | |
| 7 w/80 KHZ | 5 w/80 KHZ | 3 w/80 KHZ | 3 w/100 KHZ | 3 w/70 KHZ | 3 w/40 KHZ | |
| spd = 4 m/s | spd = 4 m/s | spd = 4 m/s | spd = 2 m/s | spd = 2 m/s | spd = 2 m/s | |
| 0.93 | 0.85 | 0.15 | 0.15 | 0.86 | 0.97 | |
| 5 w/100 KHZ | 3 w/100 KHZ | 9 w/80 KHZ | 5 w/100 KHZ | 5 w/70 KHZ | 5 w/40 KHZ | |
| spd = 4 m/s | spd = 4 m/s | spd = 4 m/s | spd = 2 m/s | spd = 2 m/s | spd = 2 m/s | |
| 0.50 | 0.02 | 1.36 | 1.22 | 1.51 | 1.51 | |
| 11 w/100 KHZ | 9 w/100 KHZ | 7 w/100 KHZ | 8 w/100 KHZ | 8 w/70 KHZ | 8 w/40 KHZ | Avg. |
| spd = 4 m/s | spd = 4 m/s | spd = 4 m/s | spd = 2 m/s | spd = 2 m/s | spd = 2 m/s | |
| 1.48 | 1.31 | 1.19 | 1.53 | 1.58 | 1.57 | 1.00 |

| 2# | | | | | | |
|---|---|---|---|---|---|---|
| 10 w/100 KHZ | 10 W 70 KHZ | 10 w/40 KHZ | 2 w/100 KHZ | 2 w 70 KHZ | 2 w 40 KHZ | |
| spd = 2 m/s | spd = 2/m/s | spd = 2 m/s | spd = 2 m/s | spd = 2 m/s | spd = 2 m/s | |
| 0.86 | 1.32 | 1.37 | 0.06 | 0.13 | 1.35 | |
| 7 w/80 KHZ | 5 w/80 KHZ | 3 w/80 KHZ | 3 w/100 KHZ | 3 w/70 KHZ | 3 w/40 KHZ | |
| spd = 4 m/s | spd = 4 m/s | spd = 4 m/s | spd = 2 m/s | spd = 2 m/s | spd = 2 m/s | |
| 0.57 | 0.71 | 0.18 | 0.18 | .47 | 1.51 | |
| 5 w/100 KHZ | 3 w/100 KHZ | 9 w/80 KHZ | 5 w/100 KHZ | 5 w/70 KHZ | 5 w/40 KHZ | |
| spd = 4 m/s | spd = 4 m/s | spd = 4 m/s | spd = 2 m/s | spd = 2 m/s | spd = 2 m/s | |
| 0.19 | 0.03 | 1.07 | 1.03 | 1.15 | 1.44 | |
| 11 w/100 KHZ | 9 w/100 KHZ | 7 w/100 KHZ | 8 w/100 KHZ | 8 w/70 KHZ | 8 w/40 KHZ | Average |
| spd = 4 m/s | spd = 4 m/s | spd = 4 m/s | spd = 2 m/s | spd = 2 m/s | spd = 2 m/s | |
| 1.08 | 0.97 | 0.73 | 1.08 | 1.24 | 1.40 | 0.84 |

### Example 2

This example includes the preparation of additional samples utilizing different base substrates and different cure techniques, i.e., UV-cure and thermal cure.

LDS additives: Copper hydroxide phosphate from Merck Chemical Co. and copper chromite black spinel purchased from Shepherd Color Company

UV based coating: the main components of a UV-based coating included acrylate monomers, acrylate oligomers, photoinitiators, diluting agents and additives. The following materials from Sartomer were evaluated: isobornyl acrylate (IBOA, SR506), 1,6-hexanediol diacrylate (HDDA, SR238), polyethylene glycol (400) diacrylate (SR 344), propoxylated 2 neopentyl glycol diacrylate (SR9003), tripropylene glycol diacrylate (TPGDA, SR306), trimethylolpropane triacrylate (TMPTA, SR351), pentaerythritol triacrylate (SR444), dipentaerythritol tetraacrylate (SR399), aliphatic urethane acrylate (CN9010, CN9013 form Sartomer and and EB 8215 from Cytec). Irgacure® 184 from BASF was used as the photoinitiator and butyl acetate was used as a solvent to dilute the coating liquid.

Thermal based coating (sample nos. 9 and 10): a two-component thermal-curing coating system was evaluated, namely Uracron CY472 E-57 (from DSM), a hydroxyl acrylic resin, which was used as the main component, and Desmodur N 3390 BA (from Bayer), an aliphatic polyisocyanate, was used as a hardener.

The coating formulations in this example are listed in Table 3. The base substrates included plastic and glass. Plastic substrates included Lexan®1414 (PC), C1200HF (PC/ABS), Lexan HFD 1034, V0150B (classical Noryl®), LTA6020 (classical Noryl®), 30% glass fiber reinforced polybutylene terephthalate (PBT), 50% glass fiber reinforced polyphthalamide (PPA), and acrylonitrile/styrene/acrylate (ASA). All plastics were injected into color chips, which were used as substrates for the coatings.

UV-based coating liquids (sample nos. 11-16) were coated on Lexan® 1414 color chips, and then were subjected to laser direct structuring followed by chemical plating. These samples showed good plating performance. The remaining samples were coated on the following substrates:

| | |
|---|---|
| 1 | Lexan ® 1414 |
| 2 | Lexan ® HFD 1034 |
| 3 | V0150B |
| 4 | LTA6020 |
| 5 | 30% glass fiber reinforced polybutylene terephthalate (PBT) |
| 6 | ASA |
| 7 | C1200HF (PC/ABS) |
| 8 | 50% glass fiber reinforced polyphthalamide (PPA) |
| 9 | Glass |
| 10 | Glass |

All coatings were diluted by butyl acetate to 50% solid content and were introduced onto the base substrate by bar coating. Then, the samples were dried at 40° C. for 10 minutes, following which, the parts (samples 1-8 and 11-16) were exposed to UV radiation (Fusion UV, H bulb, with UVA intensity at 1700 mW/cm² and UV energy at 480 mJ/cm²). Sample nos. 9 and 10 were thermally cured at 60° C. for 30 minutes.

TABLE 3
Coating Formulations (Wt. %)

| | | | | | | | Desmodur | Copper | Copper |
|---|---|---|---|---|---|---|---|---|---|
| Coating | | | | EB | | CY472 | N 3390 | hydroxide | chromite |
| No. | SR238 | SR351 | CN9010 | 8215 | 184 | E-57 | BA | phosphate | black |
| 1 | 40 | 40 | 13 | — | 7 | — | — | 2 | — |
| 2 | 40 | 40 | 13 | — | 7 | — | — | 3 | — |
| 3 | 40 | 40 | 13 | — | 7 | — | — | 5 | — |
| 4 | 40 | 40 | 13 | — | 7 | — | — | — | 2 |
| 5 | 40 | 40 | 13 | — | 7 | — | — | — | 3 |
| 6 | 40 | 40 | 13 | — | 7 | — | — | — | 5 |
| 7 | — | — | — | 93 | 7 | — | — | 5 | — |
| 8 | — | — | — | 93 | 7 | — | | — | 5 |
| 9 | — | — | — | — | — | 80 | 20 | 5 | — |
| 10 | — | — | — | — | — | 80 | 20 | — | 5 |
| 11 | 40 | 40 | 13 | — | 7 | — | — | 10 | — |
| 12 | 40 | 40 | 13 | — | 7 | — | — | 20 | — |
| 13 | 40 | 40 | 13 | — | 7 | — | — | 30 | — |
| 14 | 40 | 40 | 13 | — | 7 | — | — | — | 10 |
| 15 | 40 | 40 | 13 | — | 7 | — | — | — | 20 |
| 16 | 40 | 40 | 13 | — | 7 | — | — | — | 30 |

1. A laser direct structuring (LDS) material, comprising:
(a) a first coating layer comprising a first LDS additive, and
(b) a base substrate;
wherein the first coating layer contacts the base substrate.

2. The LDS material of claim 1, wherein the LDS material has greater than 60% light transmittance and less than 40% haze as measured by ASTM D1003-00(B).

3. The LDS material of claim 1, wherein the base substrate comprises polymer, metal, ceramic, glass, non-metallic solids, paper, wax, composites, rubber, paper, wood, insulation materials, reinforced polymeric materials, or combinations thereof.

4. The LDS material of claim 1, wherein the base substrate is a thermoplastic or a thermosetting resin.

5. The LDS material of claim 4, wherein the thermoplastic resin is selected from the group consisting of polycarbonate, acrylonitrile-butadiene-styrene, polyimide, poly(arylene ether), polyamide, polyester, polyphthalamide, polyphenylene oxide, polyetherimide, polyketones, polyetherketones, polybenzimidazole, polystyrene, polymethyl methacrylate, polyvinylchloride, cellulose-acetate, polyacrylonitrile, polysulphone, polyphenylenesulfide, fluoropolymers, polycarbonate/acrylonitrile-butadiene-styrene resin blend, acrylonitrile-ethylene/propylene-styrene, methyl methacrylate-butadiene-styrene, acrylonitrile-butadiene-methyl methacrylate-styrene, acrylonitrile-n-butyl acrylate-styrene, rubber modified polystyrene, polyethylene, polypropylene, silicone, polyamide elastomer, polyester based elastomers, and combinations thereof.

6. The LDS material of claim 4, wherein the thermosetting resin is selected from the group consisting of phenol resin, urea resin, melamine-formaldehyde resin, urea-formaldehyde latex, xylene resin, diallylphthalate resin, epoxy resin, aniline resin, furan resin, polyurethane, and combinations thereof.

7. The LDS material of claim 1, wherein the base substrate is a polycarbonate.

8. The LDS material of claim 1, wherein the first LDS additive comprises from about 2% to about 5% by weight of the coating layer.

9. The LDS material of claim 1, wherein the first LDS additive is selected from the group consisting of copper chromium oxide spinel, copper hydroxide phosphate, copper phosphate, copper chromium oxide spinel, a copper sulfate, a cuprous thiocyanate, an organic metal complex, a palladium/palladium-containing heavy metal complex, a metal oxide, a metal oxide-coated filler, antimony doped tin oxide coated on mica, a copper containing metal oxide, a zinc containing metal oxide, a tin containing metal oxide, a magnesium containing metal oxide, an aluminum containing metal oxide, a gold containing metal oxide, a silver containing metal oxide, and a combination thereof.

10. The LDS material of claim 1, wherein the first LDS additive comprises copper chromium oxide spinel, copper hydroxide phosphate, copper phosphate, or mixtures thereof.

11. The LDS material of claim 1, wherein the first coating layer is prepared from a coating liquid that is amenable to UV curing, thermal curing, or a combination thereof.

12. The LDS material of claim 11, wherein the coating liquid comprises the first LDS additive, a monomer, an oligomer, a photoinitiator, or a diluting agent, or combinations thereof.

13. The LDS material of claim 1, wherein the first coating layer has a thickness from about 3 μm to about 50 μm.

14. The LDS material of claim 1, wherein the first coating layer has a thickness from about 5 μm to about 25 μm.

15. The LDS material of claim 1, wherein the base substrate is a polymeric sheet having a top surface and a bottom surface, wherein the first coating layer comprising the first LDS additive contacts the top surface of the polymeric sheet and a second coating layer comprising a second LDS additive contacts the bottom surface of the polymeric sheet.

16. The LDS material of claim 1, wherein the base substrate is planar, cylindrical, spherical, annular, tubular, ovoid, a regular 3-D shape, or an irregular 3-D shape.

17. A method of forming the LDS material of claim 1, comprising:
depositing a coating liquid comprising a first LDS additive on the base substrate; and
curing the coating liquid on the base substrate to form the first coating layer.

18. The method of claim 17, wherein the coating liquid is deposited by spray coating, dip coating, bar coating, flow coating, powder coating, solution casting, roll-to-roll coating, screen printing, atomization, or combinations thereof.

19. The method of claim 17, further comprising
forming an activated path on the first coating layer by laser structuring; and
depositing a metal layer on the activated path.

20. An article of manufacture formed from the LDS material of claim 1, wherein an activated path is formed on the first coating layer by laser structuring and a metal layer is deposited on the activated path.
